(19) United States
(12) Patent Application Publication
(10) Pub. No.: US 2012/0220067 A1
(43) Pub. Date: Aug. 30, 2012

(54) FURNACE AND METHOD OF FORMING THIN FILM USING THE SAME

(76) Inventors: Doug-GI Ahn, Yongin-si (KR); Seoung-Jin Seo, Suwon-si (KR); Byoung-Dong Kim, Yongin-si (KR); Yong-Tack Hong, Suwon-si (KR)

(21) Appl. No.: 13/271,777

(22) Filed: Oct. 12, 2011

(30) Foreign Application Priority Data
Feb. 25, 2011 (KR) 2011-0017225

(51) Int. Cl. C23C 16/455; H01L 31/18; B05C 11/00

(52) U.S. Cl. 438/95; 118/58; 118/724; 257/E31.027

(57) ABSTRACT

A furnace includes a chamber extended in a first direction to accommodate a plurality of substrates, a process plate on which the substrates are mounted, and the process plate is disposed in the chamber and extended in the first direction. The process plate includes a plurality of thru-holes penetrating through an upper surface and a lower surface of the process plate. The furnace further includes at least one fan disposed under the lower surface to flow air in the chamber in a second direction such that the air flows from the upper surface to the lower surface through the thru-holes and a heater operatively connected to the chamber to heat the air in the chamber.

### CROSS-REFERENCE TO RELATED APPLICATION

This application claims priority under 35 U.S.C. §119 to Korean Patent Application No. 10-2011-0017225 filed on Feb. 25, 2011, the disclosure of which is hereby incorporated by reference herein in its entirety.

### BACKGROUND

1. Technical Field

The present disclosure relates to a furnace and a method of forming a thin film using the same. More particularly, the present disclosure relates to a furnace and a method of forming a thin film using the furnace.

2. Description of the Related Art

A photoelectric conversion device is used to convert light energy into electrical energy. To this end, the photoelectric conversion device includes a photoelectric conversion layer that absorbs the light energy from the exterior to cause a photovoltaic effect. Due to the photovoltaic effect, free electrons are generated, and thus current is generated. The photoelectric conversion layer may be a light absorbing layer including, for example, copper, indium, and selenium or sulfur, or including copper, indium, gallium, and selenium or sulfur. The light absorbing layer is formed by, for example, a reacting gas containing selenium or sulfur with a light absorbing precursor containing copper and indium or a light absorbing precursor containing copper, indium, and gallium.

### SUMMARY

Exemplary embodiments of the present invention provide a furnace capable of reducing a process time and an amount of reaction gas when a thin film is formed using the furnace.

Exemplary embodiments of the present invention provide a method of forming the thin film using the furnace.

According to exemplary embodiments of the present invention, a furnace includes a chamber, a process plate, at least one fan, and a heater.

The chamber is extended in a first direction to accommodate a plurality of substrates therein. The process plate on which the substrates are mounted is disposed in the chamber and extended in the first direction, and the process plate includes a plurality of thru-holes penetrating through an upper surface and a lower surface thereof. The fan is disposed under the lower surface to flow an air in the chamber in a second direction such that the air flows from the upper surface to the lower surface through the thru-holes. The heater is operatively connected to the chamber to heat the air in the chamber.

In some exemplary embodiments, the heater may be attached to an inner wall of the chamber or an outer wall of the chamber.

Each of the substrates is arranged such that the upper and lower surfaces are vertical to the first direction. In addition, the substrates are held by a substrate fixing part disposed on the upper surface of the process plate.

The substrates include an insulating substrate and a CIS (Cu—In—Se, S) based light absorbing layer precursor material disposed on the insulating substrate, and the reaction gas includes at least one of hydrogen selenide (H₂Se) and hydrogen sulfide (H₂S). In addition, each of the substrates is a single crystalline or polycrystalline silicon substrate, and the reaction gas includes phosphoryl chloride (POCl₃) or tribromoborane (BBr₃).

According to exemplary embodiments of the present invention, a method of fanning a thin film is provided as follows. When a substrate is prepared and the substrate is loaded into the furnace, a reaction gas is supplied into the chamber. Then, the fan is operated while the air in the chamber is heated in order to react the substrate with the reaction gas. The chamber may be sealed after supplying the reaction gas into the chamber.

According to exemplary embodiments of the present invention, a method of forming a thin film is provided. The method includes preparing a plurality of substrates, inserting the substrates into a substrate fixing part which is mounted on a processing plate having a plurality of process holes therein within the chamber of a furnace, and the substrates are arranged spaced apart from each other and disposed vertically in relation to a bottom surface of the chamber in the substrate fixing part, supplying a reaction gas comprising at least one of hydrogen selenide (H₂Se) and hydrogen sulfide (H₂S) into the chamber, sealing the chamber after the reaction gas has been supplied into the chamber, and heating the chamber subsequent to the sealing of the chamber to a predetermined temperature. The method further includes operating a fan disposed underneath the substrates and the processing plate while the chamber is being heated to circulate heated air in the chamber such that the heated air flows downward from an upper portion of the chamber in a direction of the bottom surface of the chamber and in between at least two adjacent substrates of the substrates to thereby contact surfaces of the at least two adjacent substrates while flowing downward in the direction of the bottom surface and then the heated air flows through the process holes of the processing plate and out of a rear surface of the processing plate.

According to the above, the thin film, which is formed in the furnace, may have substantially uniform physical characteristics throughout the substrates. In addition, manufacturing time and manufacturing can be reduced by using the furnace.

### BRIEF DESCRIPTION OF THE DRAWINGS

Exemplary embodiments of the present invention can be understood in more detail from the following detailed description when considered in conjunction with the accompanying drawings wherein:

FIG. 1 is a cross-sectional view showing a side portion of a furnace according to an exemplary embodiment of the present invention;

FIG. 2 is a cross-sectional view showing a front portion of the furnace shown in FIG. 1;

FIG. 3 is a perspective view showing a processing plate according to an exemplary embodiment of the present invention;

FIG. 4 is a perspective view showing a processing plate according to an exemplary embodiment of the present invention;

FIG. 5 is a flow chart illustrating a method of forming a thin film on a substrate using the furnace shown in FIGS. 1 and 2;

FIG. 6 is a cross-sectional view showing a photoelectric conversion cell according to an exemplary embodiment of the present invention; and

FIG. 7 is a cross-sectional view showing a photoelectric conversion device according to an exemplary embodiment of the present invention.

### DETAILED DESCRIPTION

It will be understood that when an element or layer is referred to as being “on”, “connected to” or “coupled to” another element or layer, it can be directly on, connected or coupled to the other element or layer or intervening elements or layers may be present. Like numbers refer to like elements throughout.

Hereinafter, exemplary embodiments of the present invention will be explained in detail with reference to the accompanying drawings.

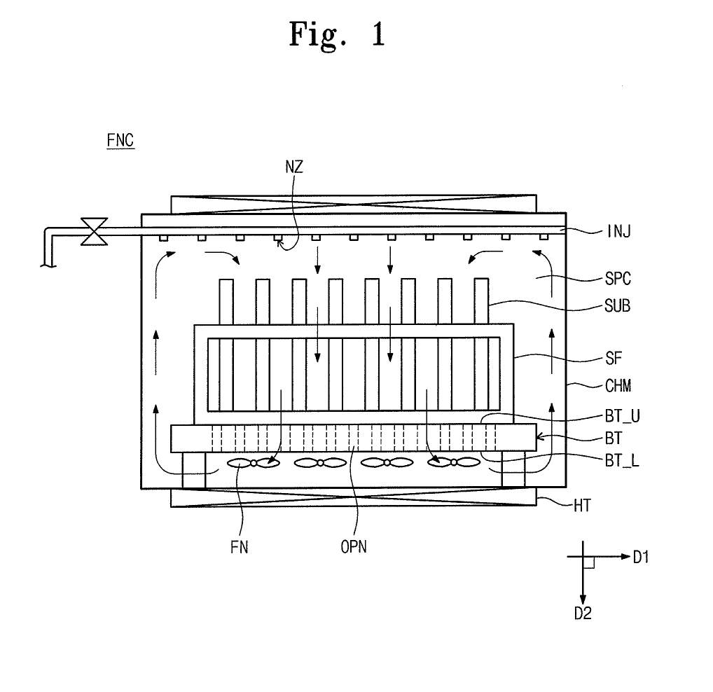

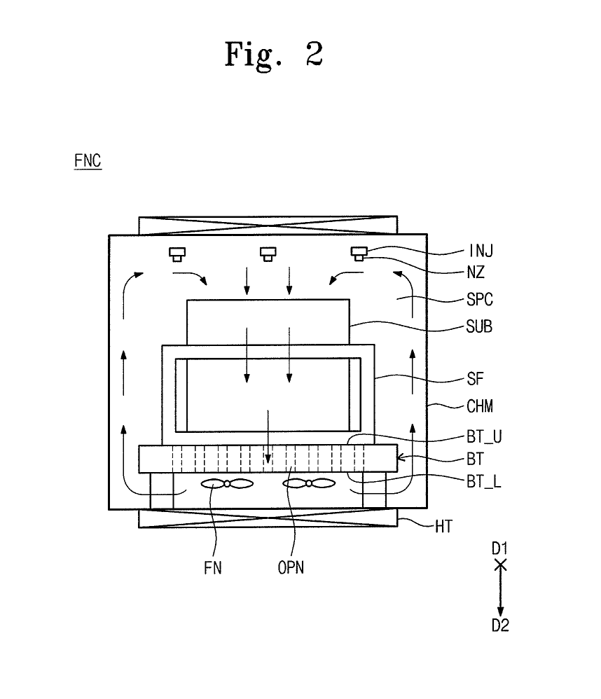

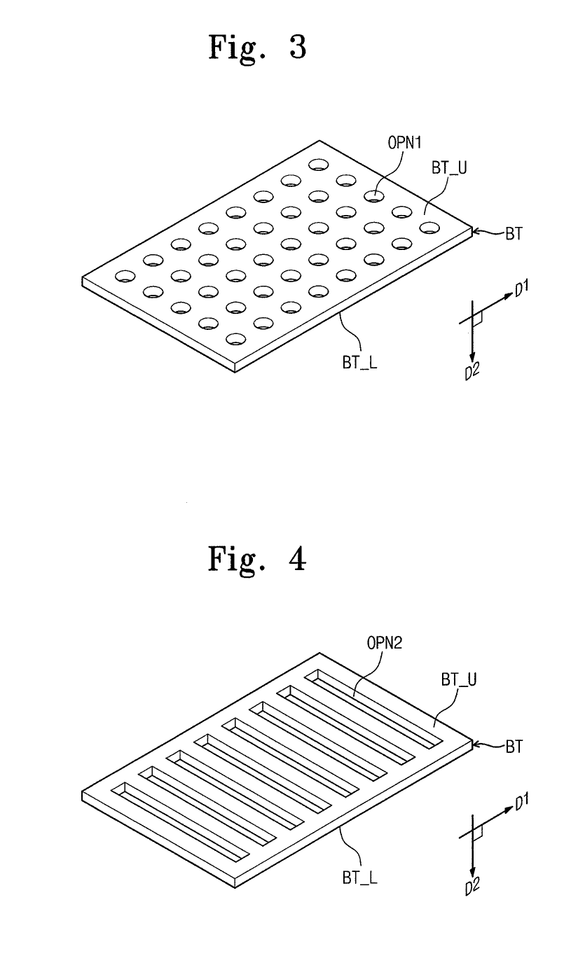

FIG. 1 is a cross-sectional view showing a side portion of a furnace according to an exemplary embodiment of the present invention and FIG. 2 is a cross-sectional view showing a front portion of the furnace shown in FIG. 1. FIG. 3 is a perspective view showing a processing plate according to an exemplary embodiment of the present invention and FIG. 4 is a perspective view showing a processing plate according to an exemplary embodiment of the present invention.

Referring to FIGS. 1 and 2, a furnace FNC includes, for example, a chamber CHM accommodating a plurality of substrates SUB, an injection pipe INJ supplying a reaction gas to the chamber CHM, a processing plate BT provided in the chamber CHM, a substrate fixing part SF disposed on the processing plate BT to hold the substrates SUB, a fan FN disposed under the processing plate BT, and a heater HT heating the air in the chamber CHM.

Each substrate SUB has, for example, a plate-like shape and is provided with two substrate surfaces. The substrates SUB are applied to various electronic devices, such as, for example, display apparatuses, photoelectric conversion devices, etc. Various substrates, such as, for example, a silicon wafer, a glass substrate, a metal substrate, a polymer substrate, etc., may be used as a base substrate for the substrates SUB. In addition, the base substrate may be formed of, for example, a transparent material and have flexibility. Each substrate SUB may have, for example, a circular plate shape or a rectangular plate shape including two facing long sides and two facing short sides perpendicular to the long sides. However, exemplary embodiments of the present invention are not limited to the above shapes for the substrate SUB but rather the shapes of the substrate SUB may be varied in accordance with exemplary embodiments of the present invention as understood by one skilled in the art.

The chamber CHM has a space SPC therein for receiving the substrates SUB. The substrates SUB is annealed or reacted with a reaction gas in the space SPC. The chamber CHM has heat resistance and includes at least one material which is not reacted with the reaction gas. For instance, when phosphoryl chloride (POCL₃) gas is used as the reaction gas, the chamber CHM may include, for example, a quartz material so as to prevent the reaction between the chamber CHM and the POCL₃.

The chamber CHM has, for example, a rectangular cylinder shape or a circular cylinder shape, which is extended in a first direction D1. It is noted that exemplary embodiments of the present invention are not limited to the above shape for the chamber CHM but rather the shape of the chamber CHM may be varied in accordance with exemplary embodiments of the present invention as understood by one skilled in the art.

In the present exemplary embodiment, the first direction D1 is, for example, one of two directions substantially parallel to the ground, but it should not be limited thereto or thereby. That is, the first direction D1 may, for example, be inclined with respect to the ground.

The injection pipe INJ supplies the reaction gas into the chamber CHM. The injection pipe INJ penetrates through the chamber CHM to supply the reaction gate into the chamber CHM. The injection pipe INJ may be removed from the furnace FNC when the furnace FNC is used only to heat the substrates SUB without relation to the reaction of the substrates SUB.

The injection pipe INJ may be extended, for example. in the first direction D1 such that the reaction gas is uniformly supplied to the chamber CHM. The injection pipe INJ includes at least one nozzle NZ arranged in the extended direction of the injection pipe INJ. The nozzle NZ has an opening to spray the reaction gas to, for example, a second direction D2 substantially perpendicular to the ground. The injection pipe INJ may include a plurality of branches each of which has plural nozzles NZ.

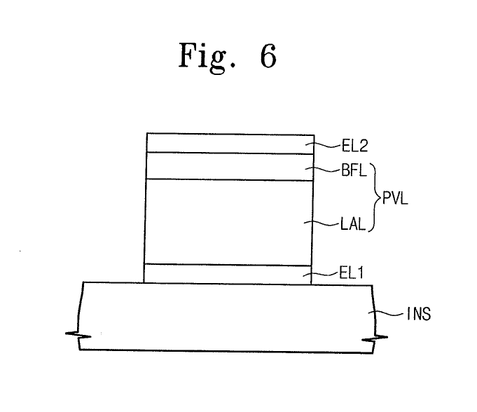

The reaction gas is supplied to the space SPC of the chamber CHM through the injection pipe INJ. The choice of the reaction gas depends on the kind of the substrates SUB or the property of thin film formed on the substrate SUB. For example, CIS (copper (Cu)-indium gallium In(Ga)-selenide (Se), sulfide (S)) based light absorbing layer applied to the photoelectric conversion device according to the present exemplary embodiment may be formed using, for example, the gas for a selenization reaction or a sulfurization reaction. For example, the gas of hydrogen selenide (H₂Se) or hydrogen sulfide (H₂S) may be used as the gas for the selenization or sulfurization reaction. Alternatively, both H₂Se and H₂S may be used as the reacting gas to form the CIS based light absorbing layer as will be described in further detail later in connection with an exemplary embodiment of the present invention discussed with regard to FIG. 6. In addition, for example, in an exemplary embodiment of the present invention, the reaction gas for a p-doped layer or n-doped layer may be used when a p-n junction for the photoelectric conversion device is formed. For example, as the reaction gas for the p-doped layer and the n-doped layer, tribromoborane (BBr₃) gas and POCL₃ gas may be used respectively. The reaction gas may be provided with, for example, a dilution gas to control its reaction degree and reaction velocity, and provided with a carrier gas to carry the reaction gas into the chamber CHM. The dilution gas or the carrier gas has a low reactivity such as, for example, an inert gas or a nitrogen gas.

The processing plate BT is disposed in the chamber CHM and has, for example, a rectangular plate shape including an upper surface BT_U and a lower surface BT_L. It is noted that exemplary embodiments of the present invention are not limited to the above shape for the processing plate BT but rather the shape of the processing plate BT may be varied in accordance with exemplary embodiments of the present invention as understood by one skilled in the art. The processing plate BT is extended, for example, in the first direction D1.

Referring to FIGS. 1 to 4, the processing plate BT includes a plurality of thru-holes OPN penetrating the upper surface BT_U and the lower surface BT_L in the second direction D2. The thru-holes OPN serves as a flow path of the air moved by the fan FN.

When viewed in a plan view, the thru-holes OPN may be, for example, thru-holes OPN1 having a circular shape as shown in FIG. 3, but the thru-holes OPN should not be limited thereto. That is, the thru-holes OPN may be, for example, thru-holes OPN2 having a slit shape as shown in FIG. 4.

The substrate fixing part SF is disposed on the processing plate BT to hold the substrates SUB. The substrate fixing part SF provides spaces into which the substrates SUB are inserted and held. The substrates SUB are inserted into the spaces and arranged to be spaced apart from each other. For example, the substrates SUB are arranged such that the substrate surfaces of each substrate SUB are vertical to the first direction D1. That is, the substrate surfaces of each substrate SUB are vertical to the ground. In addition, in the case that each substrate SUB has the rectangular plate shape including two facing long sides and two facing short sides perpendicular to the long sides, the short sides of each substrate SUB are substantially parallel to the second direction D2. Thus, when the air between two adjacent substrates to each other travels, the travel distance of the air in the second direction D2 is shorter than the travel distance of the air in the first direction D1.

The substrate fixing part SF includes plural frames connected to each other to accommodate the substrates SUB. Accordingly, although the substrates SUB are accommodated into the substrate fixing part SF, the contact area between the substrate fixing part SF and the substrates SUB can be minimized. In addition, the substrates SUB may be exposed through the space between the adjacent frames to each other, and the air in the chamber CHM may travel through the space SPC.

The fan FN is disposed under the substrates SUB. The fan FN is disposed to face the lower surface BT_L of the processing plate BT and driven to allow the air in the chamber CHM to travel in the second direction D2. The fan FN may be provided in a plural number, and the fans FN may be arranged to be spaced apart from each other at regular intervals.

The heater HT is disposed on, for example, an outer or inner wall of the chamber CHM and heats the air in the chamber CHM. To increase the reaction amount and the reaction velocity between the reaction gas and the substrates SUB, the heater HT heats the air in the chamber CHM to a predetermined temperature.

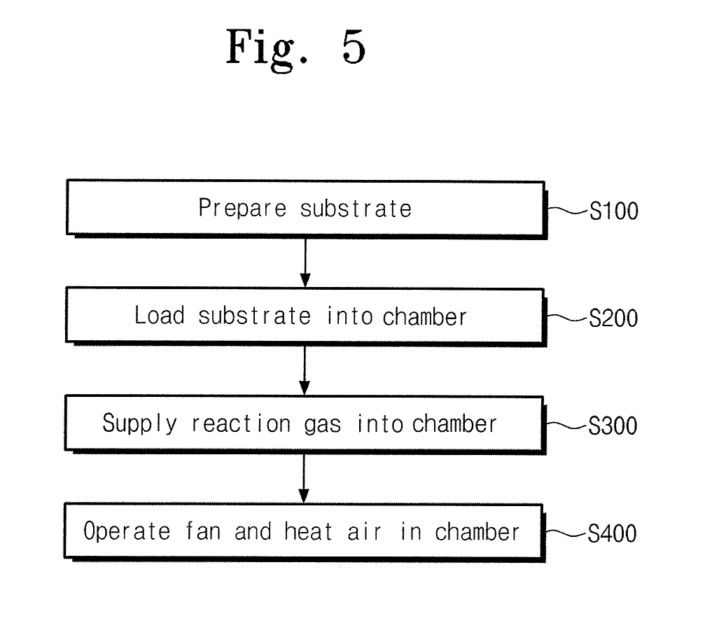

FIG. 5 is a flow chart illustrating a method of forming a thin film on the substrates using the furnace shown in FIGS. 1 and 2.

Referring to FIGS. 1, 2, and 5, the substrate SUB on which the thin film will be formed thereon is prepared (S100). The substrate SUB may be provided in a singular number or a plural number. When the plural substrates SUB are processed at the same time, the process time required to form the thin film on the substrates SUB may be significantly reduced.

Then, the substrates SUB are disposed in the chamber CHM of the furnace FNC (S200). The substrates SUB are held by the substrate fixing part SF mounted on the process plate BT in the chamber CHM.

After that, the reaction gas is supplied into the chamber CHM through the injection pipe INJ (S300). The choice of the reaction gas depends on the kind of the substrates SUB or the property of thin film formed on the substrates SUB. After supplying the reaction gas into the chamber CHM, the chamber CHM is sealed.

The chamber CHM is heated by the heater HT while the fan FN in the chamber CHM is driven (S400). Thus, the temperature in the space SPC of the chamber CHM becomes high, and the reaction gas starts the reaction with the substrates SUB, thereby forming the thin film on the substrates SUB. In addition, the air is forcibly circulated in the chamber CHM by the fan FN, and thus the reaction product, e.g., the thin film, obtained by the reaction between the reaction gas and the substrates SUB may be uniformly distributed on the substrate surfaces of the substrates SUB.

It is noted that in instances in which the fan FN is spaced apart from the substrates SUB, but the thru-holes OPN are not provided, or the fan FN is a discharge type fan, the air tends to travel on the outside of the substrates SUB without flowing between the adjacent substrates SUB and the flow amount of the air is decreased between the adjacent substrates SUB. However, according to the present exemplary embodiment, since the substrates SUB are arranged to be spaced apart from each other at the regular intervals and the fan FN, which is disposed under the substrates SUB while interposing the process plate BT, sucks the air through the thru-holes OPN and discharges the air to the rear thereof, the flow amount of the air between the adjacent substrates SUB is increased. The air between the adjacent substrates SUB makes contact with the substrate surfaces while flowing in the second direction D2. In addition, the air in the chamber CHM travels along the short sides of the substrates SUB, so the travel distance of the air traveling along the short sides of the substrates SUB is shorter than when the air travels along the long sides of the substrates SUB. Accordingly, the air may readily travel within the chamber SHM including in between the substrates SUB by way of the fan FN. As a result, although the distance between the adjacent substrates SUB is narrow, the reaction gas can readily make contact with the substrate surfaces of the substrates SUB, thereby increasing the reaction between the reaction gas and the substrate surfaces of the substrates SUB and the number of the substrates SUB accommodated in the chamber CHM.

In addition, the air heated by the heater HT travels to the upper portion of the chamber CHM because the heated air has a lower density than the air that is not heated, but the heated air travels to the lower portion of the chamber CHM, e.g., the second direction D2, by the fan FN. Thus, the temperature in the chamber CHM becomes uniform. Furthermore, in the conventional reaction gas, the composition ratio of the reaction gas in the upper portion of the chamber CHM may be different from that of the reaction gas in the lower portion of the chamber CHM due to a density difference between the reaction gases, between the reaction gas and the dilution gas, or between the reaction gas and the carrier gas. However, according to the present exemplary embodiment, the density of all gases in the chamber CHM may be uniform.

As a result, since the reaction between the reaction gas and the substrate surfaces occurs uniformly, the thin film may be uniformly distributed on the substrate surfaces of the substrates SUB as the reaction product. In addition, the reactivity of the reaction gas in the sealed chamber CHM becomes high, so that the amount of the reaction gas used for the reaction may be reduced. Further, since the plural substrates SUB may be processed at the same time, the process time required to form the thin film on the substrates SUB may be reduced and the working efficiency of the furnace FNC may be increased.

Although not shown in figures, according to an exemplary embodiment, the positions of the thru-holes OPN may be varied arranged according to the arrangement and position of the substrates SUB to optimize the flow of the air in the chamber CHM by the fan FN. For instance, the thru-holes OPN may correspond to areas between the substrates SUB in a one-to-one correspondence. Accordingly, the air between the adjacent substrates SUB to each other may flow in the second direction D2 by the fan FN through a corresponding thru-hole of the thru-holes OPN. In addition, for example, the fan FN may be positioned at a position corresponding to a corresponding thru-hole of the thru-holes OPN or a corresponding substrate of the substrates SUB.

The number and arrangement of the thru-holes OPN may depend on, for example, the shape of the thru-holes in a plan view, the size and shape of the chamber CHM, the size of the process plate BT, the number and size of the substrates SUB, the arrangement of the substrates SUB, and the number and size of the fan FN.

The furnace FNC can be used for the process of manufacturing a semiconductor device or a photoelectric conversion device. If desired, the furnace FNC can be used for only the annealing process without supplying the reaction gas. In this case, the air heated by the heater HT travels in the chamber CHM by the fan FN, thereby uniformly distributing the heat on the substrates SUB. In addition, according to an exemplary embodiment, the furnace FNC may be used as, for example, a diffusion furnace for the diffusion process to diffuse a p-type or n-type dopant into a specified layer. For example, the furnace FNC may be used when forming an active layer of a thin film transistor or diffusing the dopant of the p-n junction of the photoelectric conversion device. For example, when the photoelectric conversion device employs single crystalline and polycrystalline silicon substrates, an n-type doping layer is formed on a p-type silicon substrate or a p-type doping layer is formed on an n-type silicon substrate using the diffusion furnace, to thereby form the p-n junction on the silicon substrate. The n-type doping layer can be formed by, for example, heating the furnace FNC after loading the silicon substrate in the furnace FNC and supplying POCL₃ gas into the furnace FNC, and the p-type doping layer can be formed by heating the furnace FNC after loading the silicon substrate in the furnace FNC and supplying BBr₃ gas into the furnace FNC.

According to an exemplary embodiment, the furnace FNC can be used for the process of forming layers of electronic devices. For example, the furnace FNC according to the present exemplary embodiment can be used for a selenization process or a sulfurization process of the CIS based light absorbing layer employed to the photoelectric conversion device. The photoelectric conversion device, which is used to convert light energy into electrical energy, includes a photoelectric conversion layer that absorbs the light energy from the exterior to cause a photovoltaic effect. The photoelectric conversion layer includes the light absorbing layer to absorb the light energy and causes the photovoltaic effect, so that free electrons are generated, thereby generating current. The photoelectric conversion layer includes, for example, the p-n junction of the p-type semiconductor and the n-type semiconductor.

FIG. 6 is a cross-sectional view showing a photoelectric conversion cell according to an exemplary embodiment of the present invention.

Referring to FIG. 6, the photoelectric conversion cell includes, for example, an insulating substrate INS, a first electrode layer EL1, a photoelectric conversion layer PVL, and a second electrode layer EL2. The first electrode layer EL1 and the second electrode layer EL2 are sequentially disposed on the insulating substrate INS, and the photoelectric conversion layer PVL is disposed between the first electrode EL1 and the second electrode EL2.

The insulating substrate INS can be applied to various electronic devices, such as, for example, display apparatuses, photoelectric conversion devices, etc. For example, various substrates, such as a silicon wafer, a glass substrate, a metal substrate, a polymer substrate, etc., can be used as the insulating substrate INS. In addition, the insulating substrate INS can be formed of, for example, a transparent material and have flexibility. The insulating substrate INS may have, for example, a circular plate shape or a rectangular plate shape including two facing long sides and two facing short sides perpendicular to the long sides. It is noted, however, that exemplary embodiments of the present invention are not limited to the above shapes for the insulating substrate INS but rather the shapes of the insulating substrate INS may be varied in accordance with exemplary embodiments of the present invention as understood by one skilled in the art

The first electrode layer EL1 may be formed of a conductive material. The first electrode layer EL1 may be formed of a metal material by, for example, a sputtering process using a metal target. The first electrode layer EL1 includes at least one of the groups selected from, for example, aluminum (Al), silver (Ag), gold (Au), copper (Cu), platinum (Pt), molybdenum (Mo), chromium (Cr), and an alloy thereof. The first electrode layer EL1 may be formed of, for example, molybdenum (Mo) to achieve an ohmic contact with a light absorbing layer LAL that will be described later and stability in the selenization process. For example, the first electrode layer EL1 may have a single layer structure or a multi-layer structure using the metal alloy.

The photoelectric conversion layer PVL is disposed on the first electrode layer EL1.

The photoelectric conversion layer PVL includes, for example, the light absorbing layer LAL disposed on the first electrode layer EL1 and a buffer layer BFL disposed on the light absorbing layer LAL.

The light absorbing layer LAL converts the light from the exterior into the electrical energy using the photovoltaic effect to generate an electromotive force. The light absorbing layer LAL may be, for example, a selenide-based CIS light absorbing layer, a sulfide-based CIS light absorbing layer, or a sulfide/selenide-based CIS light absorbing layer as the p-type semiconductor layer.

The selenide-based CIS light absorbing layer may include, for example, copper indium diselenide (CuInSe₂), copper indium gallium diselenide (Cu(InGa)Se₂), or copper gallium diselenide (CuGaSe₂)). The sulfide-based CIS light absorbing layer may include, for example, copper indium sulfide (CuInS₂), Cu(InGa)S₂, or copper gallium disulfide (CuGaS₂). The sulfide/selenide-based CIS light absorbing layer may include, for example, copper indium diselenide (CuInSe₂) having copper indium di-sulfo selenide (CuIn(SSe)₂) as a surface layer, copper indium selenide (CuInSe₂) having copper indium gallium di-sulfo selenide (Cu(InGa)(SSe)₂) as a surface layer, copper indium diselenide (CuInSe₂) having copper gallium di-sulfo selenide (CuGa(SSe)₂) as a surface layer, Cu(InGa)Se₂ having copper indium di-sulfo selenide (CuIn(SSe)₂) as a surface layer, copper indium gallium di-sulfo selenide (Cu(InGa)(SSe)₂) having copper indium di-sulfo selenide (CuIn(SSe)₂) as a surface layer, copper gallium diselenide (CuGaSe₂ having copper indium di-sulfo selenide (CuIn(SSe)₂) as a surface layer, copper indium gallium diselenide (Cu(InGa)Se₂) having copper indium gallium di-sulfo selenide (Cu(InGa)(SSe)₂) as a surface layer, copper gallium diselenide (CuGaSe₂) having copper indium gallium di-sulfo selenide (Cu(InGa)(SSe)₂) as a surface layer, copper indium gallium di-selenide (Cu(InGa)Se₂) having copper gallium di-sulfo selenide (CuGa(SSe)₂) as a surface layer, or copper gallium diselenide (CuGaSe₂) having copper gallium di-sulfo selenide (CuGa(SSe)₂) as a surface layer. The CIS based light absorbing layer LAL can be formed by using the furnace FNC according to the present exemplary embodiment of the present invention.

The buffer layer BFL is the n-type semiconductor layer, so that the buffer layer BFL forms the p-n junction with the light absorbing layer LAL. The buffer layer BFL may be formed from, for example, cadmium sulfide. Although not shown in figures, the buffer layer BFL may include a high-resistance buffer layer to have a higher resistance than the second electrode layer EL2. The high-resistance buffer layer may include a transparent conductive oxide, such as, for example, indium tin oxide (ITO), zinc oxide (ZnO), indium zinc oxide (IZO), or indium tin zinc oxide (ITZO). Since a large energy band gap exists between the light absorbing layer LAL and the second electrode layer EL2, the buffer layer BFL having the band gap corresponding to an intermediate value of the energy band gap between the light absorbing layer LAL and the second electrode layer EL2 is disposed between the light absorbing layer LAL and the second electrode layer EL2. Thus, the light absorbing layer LAL and the second electrode layer EL2 form a good ohmic contact.

The second electrode layer EL2 is disposed on the buffer layer BFL, and may be formed of, for example, a transparent conductive oxide, such as tin oxide (SnO₂) indium tin oxide (ITO), zinc oxide (ZnO), indium zinc oxide (IZO), or indium tin zinc oxide (ITZO). The second electrode layer EL2 may be subjected to, for example, texture treatment and a surface area of the second electrode layer EL2 may be enlarged by the texture treatment, thereby readily capturing the light.

The photoelectric conversion cell having the above-mentioned structure absorbs the energy of the light provided from the exterior to cause the photovoltaic effect, and the free electrons generated by the photovoltaic effect provide the electromotive force.

Hereinafter, the method of forming the CIS based light absorbing layer will be described.

The CIS based light absorbing layer is formed by performing, for example, the selenization or sulfurization process on the substrates SUB after loading the substrates SUB into the furnace FNC according to the present exemplary embodiment. The substrates SUB are the insulating substrate INS including the first electrode layer EL1 and a CIS based precursor material formed on the first electrode layer EL1. The CIS based precursor material is used to form the CIS based light absorbing layer. To this end, the CIS based precursor material may include, for example, one of copper (Cu)/gallium (Ga), copper (Cu)/indium (In), and copper (Cu)-gallium (Ga)/indium (In) and may be formed by a deposition process.

The selenide-based CIS light absorbing layer is formed by the following process. First, the substrates SUB on which the CIS based precursor material is formed are loaded into the chamber CHM of the furnace FNC, and H₂Se gas is supplied into the chamber CHM with the dilution gas or the carrier gas. Then, the chamber CHM is sealed and the temperature in the chamber CHM is increased by the convection of the air in the chamber CHM while the fan FN is driven. As a result, the H₂Se gas reacts with the CIS based light absorbing layer, thereby forming the selenide-based CIS light absorbing layer.

The sulfide-based CIS light absorbing layer is formed by the following process. First, the substrates SUB on which the CIS based precursor material is formed are loaded into the chamber CHM of the furnace FNC, and H₂S gas is supplied into the chamber CHM with the dilution gas or the carrier gas. Then, the chamber CHM is sealed and the temperature in the chamber CHM is increased by the convection of the air in the chamber CHM while the fan FN is driven. As a result, the H₂S gas reacts with the CIS based light absorbing layer, thereby forming the sulfide-based CIS light absorbing layer.

The sulfide/selenide-based CIS light absorbing layer is formed by a similar process as that of the selenide-based CIS light absorbing layer or the sulfide-based CIS light absorbing layer except for the reaction gas. That is, both H₂Se and H₂S gas are supplied into the chamber CHM as the reaction gas to form the sulfide/selenide-based CIS light absorbing layer.

When the selenide-based CIS light absorbing layer, the sulfide-based CIS light absorbing layer, and the sulfide/selenide-based CIS light absorbing layer are formed, process conditions, such as, for example, the temperature in the chamber CHM, the process time at the temperature, etc., depend on the reaction degree and reaction velocity between the reaction gas and the substrates SUB.

The selenide-based CIS light absorbing layer, the sulfide-based CIS light absorbing layer, and the sulfide/selenide-based CIS light absorbing layer, which are formed in the furnace FNC as described above, may have substantially uniform physical characteristics throughout the substrates SUB. This is because the temperature in the chamber CHM of the furnace FNC may be uniformly maintained and the contactivity between the reaction gas and the substrates SUB may be increased. Thus, manufacturing time and manufacturing cost required to manufacture the photoelectric conversion device can be reduced, thereby increasing the performance of the photoelectric conversion device according to the exemplary embodiments.

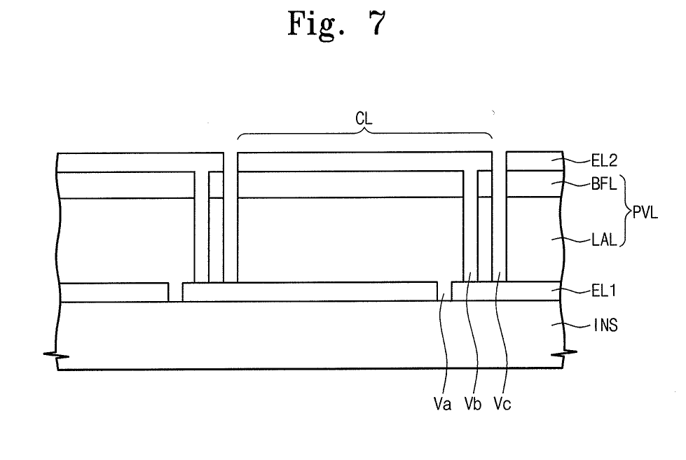

FIG. 7 is a cross-sectional view showing a photoelectric conversion device according to an exemplary embodiment of the present invention. In FIG. 7, the same reference numerals denote the same elements in FIG. 6, and thus detailed descriptions of the same elements will be omitted to avoid redundancy.

Referring to FIGS. 6 and 7, the photoelectric conversion device includes an insulating substrate INS including a plurality of cell areas. A plurality of photoelectric conversion cells CL is disposed on the insulating substrate INS to correspond to the cell areas CL, respectively. The photoelectric conversion cells CL are connected to each other in series.

Each photoelectric conversion cell CL has the similar structure and function as those of the photoelectric conversion cell shown in FIG. 6. However, each photoelectric conversion cell CL shown in FIG. 7 has a second separation recess Vb to be connected to an adjacent photoelectric conversion cell CL thereto in series.

For example, each photoelectric conversion cell CL includes a first electrode layer EL1, a photoelectric conversion layer PVL, and a second electrode layer EL2. The first electrode layer EL1 is divided into a plurality of segments respectively corresponding to the cell areas CL by a first separation recess Va, and the photoelectric conversion layer PVL is divided into a plurality of segments respectively corresponding to the cell areas CL by a third separation recess Vc.

The photoelectric conversion layer PVL includes, for example, a light absorbing layer LAL disposed on the first electrode layer EL1 and a buffer layer BFL disposed on the light absorbing layer LAL. The light absorbing layer LAL receives the light provided from the exterior and provides the electromotive force by causing the photovoltaic effect. The light absorbing layer LAL may be, for example, a selenide-based CIS light absorbing layer, a sulfide-based CIS light absorbing layer, or a sulfide/selenide-based CIS light absorbing layer as the p-type semiconductor layer, and may be formed using the furnace FNC according to exemplary embodiments of the present invention.

The first separation recess Va and the third separation recess Vc may be formed by, for example, a laser process. In addition, the second separation recess Vb may be formed, for example, by patterning the photoelectric conversion cell PVL using the laser process, thereby exposing the first electrode layer EL1 of the photoelectric conversion cell CL adjacent thereto. It is noted that exemplary embodiments of the present invention are not limited to using a laser process for forming the above-mentioned first separation recess Va, second separation recess Vb and third separation recess Vc but rather other processes known by those skilled in the art may also be used for forming the first separation recess Va, the second separation recess Vb and the third separation recess Vc in accordance with exemplary embodiments of the present invention. The second electrode layer EL2 is electrically connected to the first electrode layer EL1 of the adjacent photoelectric conversion cell CL thereto through the second separation recess Vb. As described above, the photoelectric conversion cells CL may be connected to each other in series.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A furnace comprising:
a chamber extended in a first direction to accommodate a plurality of substrates;
a process plate on which the substrates are mounted, the process plate is disposed in the chamber and extended in the first direction, the process plate comprising a plurality of thru-holes penetrating through an upper surface and a lower surface of the process plate;
at least one fan disposed under the lower surface to flow air in the chamber in a second direction such that the air flows from the upper surface to the lower surface through the thru-holes; and
a heater operatively connected to the chamber to heat the air in the chamber.

2. The furnace of claim 1, wherein each of the substrates has a plate-like shape having two substrate surfaces and the substrate surfaces are arranged substantially vertical to the first direction.

3. The furnace of claim 2, further comprising a substrate fixing part disposed on the process plate to hold the substrates therein.

4. The furnace of claim 2, wherein the substrates are spaced apart from each other and each of the thru-holes is positioned corresponding to a position between two adjacent substrates among the substrates.

5. The furnace of claim 4, wherein the fan is provided in a plural number and the fans are located at locations, each corresponding to s location between the two adjacent substrates among the substrates.

6. The furnace of claim 1, further comprising an injection pipe that supplies a reaction gas into the chamber.

7. The furnace of claim 6, wherein the injection pipe is extended in the first direction and further comprises nozzles to spray the reaction gas to the second direction.

8. The furnace of claim 7, wherein each of the substrates comprises an insulating substrate and a CIS based light absorbing layer precursor material disposed on the insulating substrate, and the reaction gas comprises at least one of hydrogen selenide (H₂Se) and hydrogen sulfide (H₂S).

9. The furnace of claim 8, wherein the precursor material comprises copper gallium (Cu—Ga), copper indium (Cu—In), or copper gallium indium (Cu—Ga—In).

10. The furnace of claim 7, wherein each of the substrates is a single crystalline or polycrystalline silicon substrate, and the reaction gas comprises phosphoryl chloride (POCl₃) or tribromoborane (BBr₃).

11. The furnace of claim 1, wherein the thru-holes have a circular shape when viewed in a plan view.

12. The furnace of claim 1, wherein the thru-holes have a slit shape when viewed in a plan view.

13. The furnace of claim 1, wherein the chamber has a rectangular cylinder shape or a circular cylinder shape, which is extended in the first direction.

14. A method of forming a thin film, comprising:
preparing a substrate;
loading the substrate into the furnace of claim 1;
supplying a reaction gas into the chamber; and
operating the fan while the air in the chamber is heated to react the substrate with the reaction gas.

15. The method of claim 14, further comprising sealing the chamber after supplying the reaction gas into the chamber.

16. The method of claim 14, wherein the substrate comprises an insulating substrate and a CIS based light absorbing layer precursor material disposed on the insulating substrate, and the reaction gas comprises at least one of hydrogen selenide (H₂Se) and hydrogen sulfide (H₂S).

17. The method of claim 16, wherein the precursor material comprises copper gallium (Cu—Ga), copper indium (Cu—In), or copper gallium indium (Cu—Ga—In).

18. The method of claim 17, wherein each of the substrates is a single crystalline or polycrystalline silicon substrate, and the reaction gas comprises phosphoryl chloride (POCl₃) or tribromoborane (BBr₃).

19. The furnace of claim 1, wherein the heater is disposed on an inner wall of the chamber or an outer wall of the chamber.

20. A method of forming a thin film, comprising:
preparing a plurality of substrates; inserting the substrates into a substrate fixing part which is mounted on a processing plate within the chamber of a furnace, wherein the substrates are arranged spaced apart from each other and disposed vertically in relation to a bottom surface of the chamber in the substrate fixing part;
supplying a reaction gas comprising at least one of hydrogen selenide (H2Se) and hydrogen sulfide (H2S) into the chamber;
sealing the chamber after the reaction gas has been supplied into the chamber;
heating the chamber subsequent to the sealing of the chamber to a predetermined temperature;
operating a fan disposed underneath the substrates and the processing plate while the chamber is being heated to circulate heated air in the chamber such that the heated air flows downward from an upper portion of the chamber in a direction of the bottom surface of the chamber and in between at least two adjacent substrates of the substrates to thereby contact surfaces of the at least two adjacent substrates while flowing downward in the direction of the bottom surface and then the heated air flows through thru-holes of the processing plate and out of a rear surface of the processing plate.

21. The method of claim 20, wherein the reaction gas is supplied into the reaction chamber with at least one of a dilution gas and a carrier gas, and wherein the dilution gas and the carrier gas each include one of an inert gas or a nitrogen gas.
